(19) United States
(12) Patent Application Publication
(10) Pub. No.: US 2026/0255625 A1
(43) Pub. Date: Aug. 27, 2026

(54) SEMICONDUCTOR DEVICE

(71) Applicants: KABUSHIKI KAISHA TOSHIBA, Kawasaki-shi (JP); TOSHIBA ELECTRONIC DEVICES & STORAGE CORPORATION, Kawasaki-shi (JP)

(72) Inventors: Mariko SHIMIZU, Setagaya (JP); Yosuke KAJIWARA, Yokohama (JP); Ryoma KANEKO, Ota (JP); Naoki IKEDA, Kawasaki (JP); Miyoko SHIMADA, Yokohama (JP); Ikuo FUJIWARA, Yokohama (JP); Aya SHINDOME, Yokohama (JP)

(73) Assignees: KABUSHIKI KAISHA TOSHIBA, Kawasaki-shi (JP); TOSHIBA ELECTRONIC DEVICES & STORAGE CORPORATION, Kawasaki-shi (JP)

(21) Appl. No.: 19/438,720

(22) Filed: Jan. 2, 2026

(30) Foreign Application Priority Data
Jan. 9, 2025 (JP) 2025-003608

(51) Int. Cl. H10D 30/47; H10D 62/85; H10D 64/27

(52) U.S. Cl. CPC H10D 30/475; H10D 62/8503; H10D 64/411

(57) ABSTRACT

According to one embodiment, a semiconductor device includes first to third electrodes, a semiconductor layer, a first insulating layer, and a second insulating layer. The semiconductor layer includes a first semiconductor region including Alₓ₁Ga₁₋ₓ₁N (0≤x1<1), and a second semiconductor region including Alₓ₂Ga₁₋ₓ₂N (x1<x2≤1). At least a part of a first electrode portion of the third electrode is between first and second semiconductor portions of the second semiconductor region. The second insulating layer includes a first insulating portion, a second insulating portion, and a third insulating portion. The first semiconductor portion is between the fourth partial region of the first semiconductor region and the first insulating portion in the second direction. The third insulating portion is in contact with the sixth partial region of the first semiconductor region.

### CROSS-REFERENCE TO RELATED APPLICATIONS

This application is based upon and claims the benefit of priority from Japanese Patent Application No. 2025-003608, filed on Jan. 9, 2025; the entire contents of which are incorporated herein by reference.

### FIELD

Embodiments described herein relate generally to a semiconductor device.

### BACKGROUND

For example, it is desired to improve the characteristics of semiconductor devices such as transistors.

### BRIEF DESCRIPTION OF THE DRAWINGS

FIG. 1 is a schematic cross-sectional view illustrating a semiconductor device according to a first embodiment;

FIG. 2 is a schematic cross-sectional view illustrating a semiconductor device according to the first embodiment;

FIG. 3 is a schematic cross-sectional view illustrating a semiconductor device according to a second embodiment;

FIG. 4 is a schematic cross-sectional view illustrating a semiconductor device according to the second embodiment; and

FIG. 5 is a graph illustrating the characteristics of a semiconductor device.

### DETAILED DESCRIPTION

According to one embodiment, a semiconductor device includes a first electrode, a second electrode, a third electrode, a semiconductor layer, a first insulating layer, and a second insulating layer. The third electrode is between the first electrode and the second electrode in a first direction from the first electrode to the second electrode. At least a part of the first insulating layer is provided between the third electrode and the semiconductor layer. The semiconductor layer includes a first semiconductor region including Alₓ₁Ga₁₋ₓ₁N (0≤x1<1), and a second semiconductor region including Alₓ₂Ga₁₋ₓ₂N (x1<x2≤1). The first semiconductor region includes a first partial region, a second partial region, a third partial region, a fourth partial region, a fifth partial region, and a sixth partial region. A second direction from the first partial region to the first electrode crosses the first direction. A direction from the second partial region to the second electrode is along the second direction. A direction from the third partial region to the first electrode portion is along the second direction. A fourth position of the fourth partial region in the first direction is between a first position of the first partial region in the first direction and a third position of the third partial region in the first direction. A fifth position of the fifth partial region in the first direction is between the third position and a second position of the second partial region in the first direction. A sixth position of the sixth partial region in the first direction is between the third position and the fifth position. The second semiconductor region includes a first semiconductor portion and a second semiconductor portion. At least a part of the first electrode portion is between the first semiconductor portion and the second semiconductor portion in the first direction. The second insulating layer includes a first insulating portion, a second insulating portion, and a third insulating portion. The first semiconductor portion is between the fourth partial region and the first insulating portion in the second direction. The second semiconductor portion is between the fifth partial region and the second insulating layer in the second direction. The third insulating portion is in contact with the sixth partial region.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

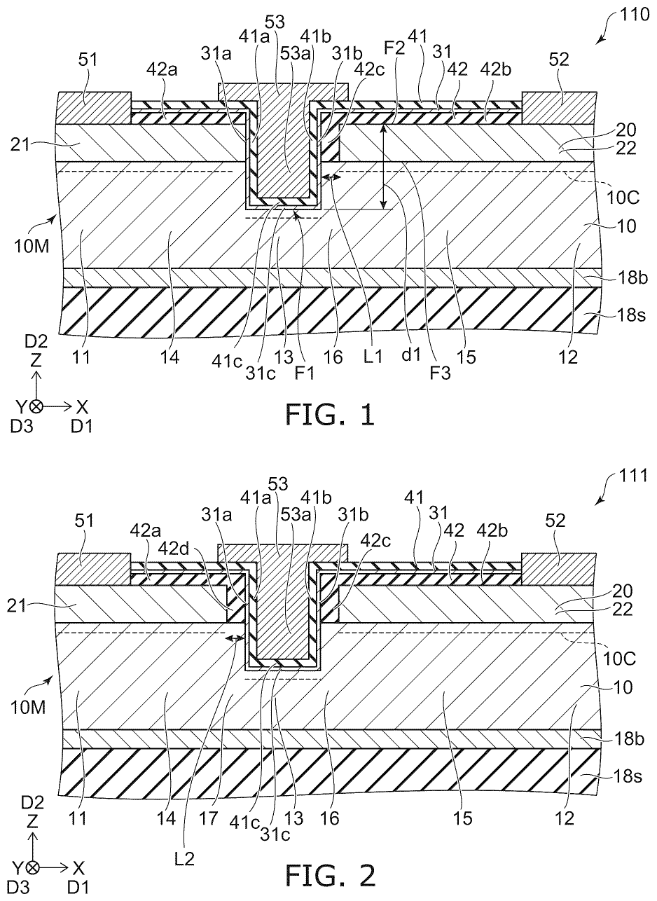

FIG. 1 is a schematic cross-sectional view illustrating a semiconductor device according to the first embodiment.

As shown in FIG. 1, a semiconductor device 110 according to the embodiment includes a first electrode 51, a second electrode 52, a third electrode 53, a semiconductor layer 10M, a first insulating layer 41, and a second insulating layer 42.

A first direction D1 from the first electrode 51 to the second electrode 52 is defined as an X-axis direction. One direction perpendicular to the X-axis direction is defined as a Z-axis direction. A direction perpendicular to the X-axis direction and the Z-axis direction is defined as a Y-axis direction.

The third electrode 53 includes a first electrode portion 53a. The third electrode 53 is provided between the first electrode 51 and the second electrode 52 in the first direction D1 from the first electrode 51 to the second electrode 52.

At least a part of the first insulating layer 41 is provided between the third electrode 53 and the semiconductor layer 10M. The first insulating layer 41 provides insulation between the third electrode 53 and the semiconductor layer 10M.

The semiconductor layer 10M includes a first semiconductor region 10 including Alₓ₁Ga₁₋ₓ₁N (0≤x1<1) and a second semiconductor region 20 including Alₓ₂Ga₁₋ₓ₂N (x1<x2≤1). The composition ratio x1 is, for example, not less than 0 and not more than 0.1. The first semiconductor region 10 includes, for example, GaN. The composition ratio x2 is, for example, not less than 0.15 and not more than 0.35. The second semiconductor region 20 includes, for example, AlGaN. These semiconductor regions may not include substantially any impurities that provide conductivity.

The first semiconductor region 10 includes a first partial region 11, a second partial region 12, a third partial region 13, a fourth partial region 14, a fifth partial region 15, and a sixth partial region 16. A second direction D2 from the first partial region 11 to the first electrode 51 crosses the first direction D1. The second direction D2 is, for example, the X-axis direction.

A direction from the second partial region 12 to the second electrode 52 is along the second direction D2. A direction from the third partial region 13 to the first electrode portion 53a is along the second direction D2. For example, a region overlapping the first electrode 51 in the second direction D2 corresponds to the first partial region 11. For example, a region overlapping the second electrode 52 in the second direction D2 corresponds to the second partial region 12. For example, a region overlapping the first electrode portion 53a in the second direction D2 corresponds to the third partial region 13.

A fourth position in the first direction D1 of the fourth partial region 14 is between a first position in the first direction D1 of the first partial region 11 and a third position in the first direction D1 of the third partial region 13. A fifth position in the first direction D1 of the fifth partial region 15 is between the third position and a second position in the first direction D1 of the second partial region 12. A sixth position in the first direction D1 of the sixth partial region 16 is between the third position and the fifth position.

The second semiconductor region 20 includes a first semiconductor portion 21 and a second semiconductor portion 22. At least a part of the first electrode portion 53a is between the first semiconductor portion 21 and the second semiconductor portion 22 in the first direction D1.

The second insulating layer 42 includes a first insulating portion 42a, a second insulating portion 42b, and a third insulating portion 42c. The first semiconductor portion 21 is between the fourth partial region 14 and the first insulating portion 42a in the second direction D2. The second semiconductor portion 22 is between the fifth partial region 15 and the second insulating portion 42b in the second direction D2. The third insulating portion 42c contacts the sixth partial region 16.

A current flowing between the first electrode 51 and the second electrode 52 can be controlled by a potential of the third electrode 53. The potential of the third electrode 53 may be a potential based on a potential of the first electrode 51. The first electrode 51 functions, for example, as one of a source electrode and a drain electrode. The second electrode 52 functions, for example, as the other of the source electrode and the drain electrode. The third electrode 53 functions, for example, as a gate electrode. The semiconductor device is a transistor.

For example, the first semiconductor region 10 includes a portion facing the second semiconductor region 20. A carrier region 10C may be formed in this portion. The carrier region 10C is, for example, a two-dimensional electron gas. The semiconductor device 110 is, for example, a High Electron Mobility Transistor.

For example, a distance between the first electrode 51 and the third electrode 53 is shorter than a distance between the third electrode 53 and the second electrode 52. Stable operation is obtained. For example, the first electrode 51 functions as the source electrode, and the second electrode 52 functions as the drain electrode.

As already explained, at least a part of the first electrode portion 53a is between the first semiconductor portion 21 and the second semiconductor portion 22 in the first direction D1. The third electrode 53 is, for example, a recessed gate electrode. This allows, for example, a high threshold voltage to be obtained. For example, normally-off operation is obtained.

As described above, in the semiconductor device 110, the third insulating portion 42c is provided. The third insulating portion 42c contacts the sixth region 16. In the portion (sixth region 16) where the third insulating portion 42c is provided, the carrier region 10C is not substantially generated when no voltage is applied to the third electrode 53. This allows a high threshold voltage to be stably obtained. For example, normally-off operation is stably obtained. According to the embodiment, a semiconductor device capable of improving characteristics can be provided.

As shown in FIG. 1, a length of the third insulating portion 42c along the first direction D1 is defined as a first length L1. The first length L1 is not excessively long. The first length L1 may be, for example, not less than 200 nm and not more than 2000 nm. This allows a practical threshold voltage to be obtained.

The third insulating portion 42c is located between the first electrode portion 53a and the second semiconductor portion 22 in the first direction D1.

In the embodiment, at least a part of the second insulating layer 42 may be amorphous. For example, at least a part of the third insulating portion 42c may be amorphous. For example, the carrier region 10C is not formed stably.

The second insulating layer 42 may include silicon and at least one selected from the group consisting of nitrogen and oxygen. For example, the second insulating layer 42 includes silicon and nitrogen. This makes it easier to maintain high crystallinity in the first semiconductor portion 21 and the second semiconductor portion 22, for example.

The third insulating portion 42c includes silicon and at least one selected from the group consisting of nitrogen and oxygen. For example, the third insulating portion 42c includes silicon and nitrogen. This makes it easier to maintain high crystallinity, for example, in the surface part of the sixth partial region 16. High mobility can be maintained.

As shown in FIG. 1, a part of the first electrode portion 53a is between the fourth partial region 14 and the sixth partial region 16 in the first direction D1. A part of the first electrode portion 53a is between two portions of the first semiconductor region 10 in the first direction D1. This makes it possible to stably obtain a high threshold voltage.

As shown in FIG. 1, the first insulating layer 41 may include a first insulating region 41a, a second insulating region 41b, and a third insulating region 41c. At least a part of the first insulating region 41a is between the first semiconductor portion 21 and the first electrode portion 53a in the first direction D1. At least a part of the second insulating region 41b is between the first electrode portion 53a and the second semiconductor portion 22 in the first direction D1. The third insulating region 41c is between the third partial region 13 and the first electrode portion 53a in the second direction D2.

The first insulating layer 41 may include, for example, silicon and at least one selected from the group consisting of nitrogen and oxygen. The first insulating layer 41 may include, for example, silicon and oxygen. High insulation is easily obtained. The first insulating layer 41 may include, for example, SiO₂.

As shown in FIG. 1, the semiconductor device 110 may further include a first compound semiconductor layer 31 including Al_{z1}Ga_{1-z1}N (x2<z1≤1). The composition ratio z1 may be, for example, not less than 0.8 and not more than 1. The first compound semiconductor layer 31 may include, for example, AlN.

The first compound semiconductor layer 31 includes, for example, a first compound semiconductor region 31a, a second compound semiconductor region 31b, and a third compound semiconductor region 31c.

A part of the first compound semiconductor layer 31 (the third compound semiconductor region 31c) is provided between the third partial region 13 and the first electrode portion 53a. The third compound semiconductor region 31c is provided, for example, between the third partial region 13 and the third insulating region 41c.

The first compound semiconductor region 31a is provided between the first semiconductor portion 21 and the first electrode portion 53a in the first direction D1. The first compound semiconductor region 31a is provided between the first semiconductor portion 21 and the first insulating region 41a in the first direction D1.

The second compound semiconductor region 31b is provided between the first electrode portion 53a and the second semiconductor portion 22 in the first direction D1. The second compound semiconductor region 31b is provided between the second insulating region 41b and the second semiconductor portion 22 in the first direction D1.

The third insulating portion 42c is between the sixth partial region 16 and another part of the first compound semiconductor layer 31 in the second direction D2. For example, a part of the first compound semiconductor layer 31 may be between a part of the first electrode portion 53a and the sixth partial region 16 in the first direction D1.

As shown in FIG. 1, the third partial region 13 includes a first face F1 that faces the first electrode portion 53a in the second direction D2. The second semiconductor region 20 includes a second face F2 and a third face F3. The third face F3 faces the first semiconductor region 10. The third face F3 is between the first semiconductor region 10 and the second face F2 in the second direction D2. The first face F1 corresponds to the upper face of the bottom of a trench provided in the semiconductor layer 10M. The second face F2 corresponds to the upper face of the semiconductor layer 10M.

A distance between the first face F1 and the second face F2 along the second direction D2 is defined as a first distance d1. In the embodiment, the first distance d1 may be, for example, not less than 10 nm and not more than 500 nm. The first distance d1 may be, for example, not less than 10 nm and not more than 2000 nm. An appropriate threshold voltage is obtained.

As shown in FIG. 1, the semiconductor device 110 may include a base body 18s. The base body 18s may be, for example, a silicon substrate. The semiconductor device 110 may include a nitride layer 18b. The nitride layer 18b is provided between the base body 18s and the first semiconductor region 10. The nitride layer 18b includes, for example, Al, Ga, and N. The nitride layer 18b is, for example, a buffer layer.

The first electrode 51, the second electrode 52, and the third electrode 53 extend along a third direction D3. The third direction D3 crosses a plane including the first direction D1 and the second direction D2. The third direction D3 may be, for example, the Y-axis direction.

FIG. 2 is a schematic cross-sectional view illustrating a semiconductor device according to the first embodiment.

As shown in FIG. 2, in semiconductor device 111 according to the embodiment, the second insulating layer 42 includes a fourth insulating portion 42d. Except for this, the configuration of the semiconductor device 111 is similar to the configuration of the semiconductor device 110.

In the semiconductor device 111, the first semiconductor region 10 further includes a seventh partial region 17. A seventh position in the first direction D1 of the seventh partial region 17 is between the fourth position in the first direction D1 of the fourth partial region 14 and the third position in the first direction D1 of the third partial region 13. The fourth insulating portion 42d in the second insulating layer 42 contacts the seventh partial region 17. As a result, the carrier region 10C is not substantially formed in the seventh partial region 17. A high threshold voltage is stably obtained.

The fourth insulating portion 42d is between the first semiconductor portion 21 and the first electrode portion 53a in the first direction D1.

A length of the fourth insulating portion 42d along the first direction D1 is defined as a second length L2. The second length L2 may be, for example, not less than 200 nm and not more than 2000 nm.

### Second Embodiment

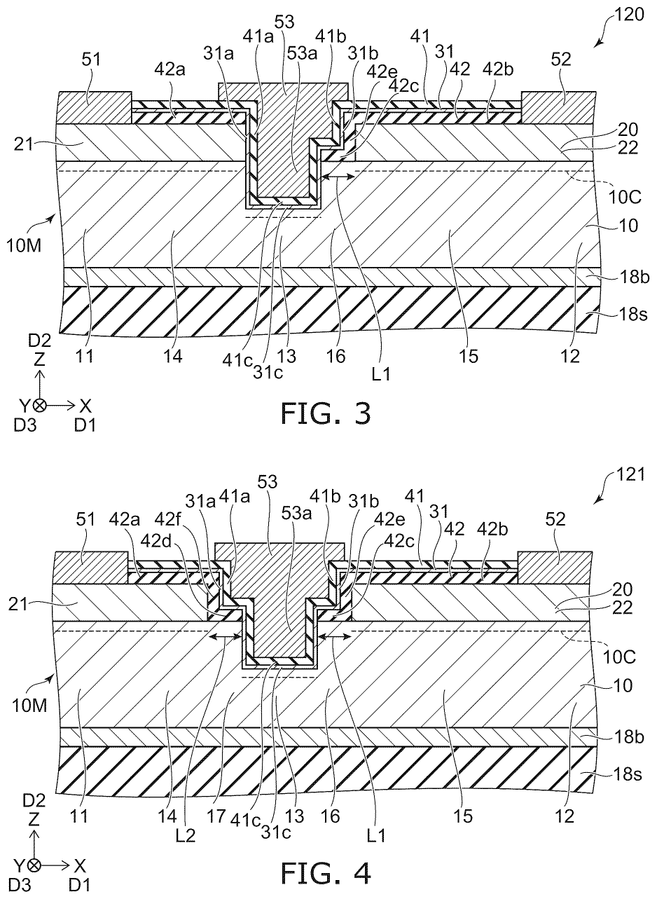

FIG. 3 is a schematic cross-sectional view illustrating a semiconductor device according to a second embodiment.

As shown in FIG. 3, in a semiconductor device 120 according to the embodiment, the third electrode 53 is stepped. Except for this, the configuration of the semiconductor device 120 is similar to the configuration of the semiconductor device 110.

In the semiconductor device 120, the third insulating portion 42c is between the sixth partial region 16 and a part of the first electrode portion 53a in the second direction D2. For example, the third insulating portion 42c is between the sixth partial region 16 and at least a part of the second insulating region 41b in the second direction D2.

For example, the second insulating layer 42 may further include a fifth insulating portion 42e. The fifth insulating portion 42e is between the second insulating region 41b and the second semiconductor portion 22 in the first direction D1. In this semiconductor device 120 as well, a high threshold voltage can be stably obtained.

FIG. 4 is a schematic cross-sectional view illustrating a semiconductor device according to the second embodiment.

As shown in FIG. 4, in a semiconductor device 121 according to the embodiment, the third electrode 53 is stepped even in the portion on the side of the first electrode 51. Except for this, the configuration of the semiconductor device 121 is similar to the configuration of the semiconductor device 111.

In the semiconductor device 121, the fourth insulating portion 42d is between the seventh partial region 17 and a part of the first electrode portion 53a in the second direction D2. The fourth insulating portion 42d is between the seventh partial region 17 and at least a part of the first insulating region 41a in the second direction D2.

For example, the second insulating layer 42 may further include a sixth insulating portion 42f. The sixth insulating portion 42f is between the first semiconductor portion 21 and the first insulating region 41a in the first direction D1. In such a semiconductor device 121 as well, a high threshold voltage can be stably obtained.

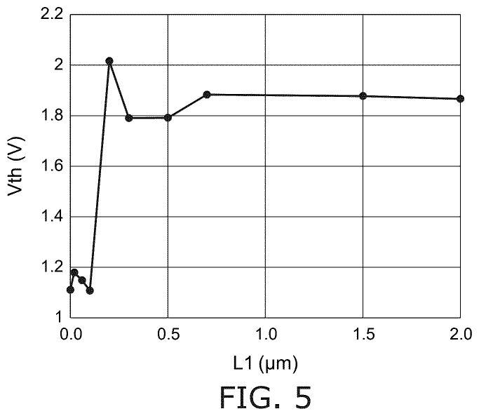

FIG. 5 is a graph illustrating the characteristics of a semiconductor device.

FIG. 5 illustrates calculation results regarding the characteristics when the first length L1 is changed in the configuration of the semiconductor device 110. The horizontal axis of FIG. 5 is the first length L1. As already explained, the first length L1 is the length of the third insulating portion 42c along the first direction D1. The vertical axis is the threshold voltage Vth. The state in which the first length L1 is 0 μm corresponds to a state in which the third insulating portion 42c is not provided.

As shown in FIG. 5, as the first length L1 becomes longer, the threshold voltage Vth becomes higher. When the first length L1 is 0.2 μm or more, a sufficiently high threshold voltage Vth is obtained. The first length L1 may be 2.0 μm or more. A sufficiently high threshold voltage Vth is stably obtained. In the embodiment, the first length L1 may be 0.2 μm or more. In the embodiment, the second length L2 may be 0.2 μm or more. For practical purposes, each of the first length L1 and the second length L2 may be 2.0 μm or less.

In the embodiment, information regarding the shape of the nitride region is obtained, for example, from an electron microscope image. Information regarding the composition and element concentration is obtained, for example, from EDX (Energy Dispersive X-ray Spectroscopy) or SIMS (Secondary Ion Mass Spectrometry). Information regarding the crystal structure may be obtained, for example, from reciprocal space mapping.

Embodiments may include the following Technical proposals:

### Technical Proposal 1

A semiconductor device, comprising:
a first electrode;
a second electrode;
a third electrode including a first electrode portion, the third electrode being between the first electrode and the second electrode in a first direction from the first electrode to the second electrode;
a semiconductor layer:
a first insulating layer; and
a second insulating layer,
at least a part of the first insulating layer being provided between the third electrode and the semiconductor layer,
the semiconductor layer including:
   a first semiconductor region including Alₓ₁Ga₁₋ₓ₁N (0≤x1<1); and
   a second semiconductor region including Alₓ₂Ga₁₋ₓ₂N (x1<x2≤1),
the first semiconductor region including a first partial region, a second partial region, a third partial region, a fourth partial region, a fifth partial region, and a sixth partial region,
a second direction from the first partial region to the first electrode crossing the first direction,
a direction from the second partial region to the second electrode being along the second direction,
a direction from the third partial region to the first electrode portion being along the second direction,
a fourth position of the fourth partial region in the first direction being between a first position of the first partial region in the first direction and a third position of the third partial region in the first direction,
a fifth position of the fifth partial region in the first direction being between the third position and a second position of the second partial region in the first direction,
a sixth position of the sixth partial region in the first direction being between the third position and the fifth position,
the second semiconductor region including a first semiconductor portion and a second semiconductor portion,
at least a part of the first electrode portion being between the first semiconductor portion and the second semiconductor portion in the first direction,
the second insulating layer including a first insulating portion, a second insulating portion, and a third insulating portion,
the first semiconductor portion being between the fourth partial region and the first insulating portion in the second direction,
the second semiconductor portion being between the fifth partial region and the second insulating layer in the second direction,
the third insulating portion being in contact with the sixth partial region.

### Technical Proposal 2

The semiconductor device according to Technical proposal 1, wherein
the third insulating portion is between the first electrode portion and the second semiconductor portion in the first direction.

### Technical Proposal 3

The semiconductor device according to Technical proposal 1 or 2, wherein
at least a part of the second insulating layer is amorphous.

### Technical Proposal 4

The semiconductor device according to any one of Technical proposals 1-3, wherein
the second insulating layer includes silicon and at least one selected from the group consisting of nitrogen and oxygen.

### Technical Proposal 5

The semiconductor device according to any one of Technical proposals 1-3, wherein
the second insulating layer includes silicon and nitrogen.

### Technical Proposal 6

The semiconductor device according to any one of technical proposals 1-5, wherein
a part of the first electrode portion is between the fourth partial region and the sixth partial region in the first direction.

### Technical Proposal 7

The semiconductor device according to any one of Technical proposals 1-6, wherein
a first length of the third insulating portion along the first direction is not less than 200 nm and not more than 2000 nm.

### Technical Proposal 8

The semiconductor device according to any one of Technical proposals 1-7, wherein
the third insulating portion is between the sixth partial region and a part of the first electrode portion in the second direction.

### Technical Proposal 9

The semiconductor device according to any one of Technical proposals 1-7, wherein
the first insulating layer includes a first insulating region, a second insulating region, and a third insulating region,
at least a part of the first insulating region is between the first semiconductor portion and the first electrode portion in the first direction,
at least a part of the second insulating region is between the first electrode portion and the second semiconductor portion in the first direction, and
the third insulating region is between the third partial region and the first electrode portion in the second direction,

### Technical Proposal 10

The semiconductor device according to Technical proposal 9, wherein
the third insulating portion is between the sixth partial region and at least a part of the second insulating region in the second direction.

### Technical Proposal 11

The semiconductor device according to Technical proposal 10, wherein
the second insulating layer further includes a fifth insulating portion, and
the fifth insulating portion is between the second insulating region and the second semiconductor portion in the first direction.

### Technical Proposal 12

The semiconductor device according to Technical proposal 9, wherein
the first semiconductor region further includes a seventh partial region,
a seventh position of the seventh partial region in the first direction is between the fourth position and the third position,
the second insulating layer further includes a fourth insulating portion,
the fourth insulating portion is in contact with the seventh partial region.

### Technical Proposal 13

The semiconductor device according to Technical proposal 12, wherein
the fourth insulating portion is between the first semiconductor portion and the first electrode portion in the first direction.

### Technical Proposal 14

The semiconductor device according to Technical proposal 12 or 13, wherein
a second length of the fourth insulating portion along the first direction is not less than 200 nm and not more than 2000 nms.

### Technical Proposal 15

The semiconductor device according to any one of Technical proposals 12-14, wherein
the fourth insulating portion is between the seventh partial region and at least a part of the first insulating region in the second direction.

### Technical Proposal 16

The semiconductor device according to Technical proposal 10, wherein
the second insulating layer further includes a sixth insulating portion, and
the sixth insulating portion is between the first semiconductor portion and the first insulating region in the first direction.

### Technical Proposal 17

The semiconductor device according to any one of Technical proposals 1-16, further comprising:
a first compound semiconductor layer including Al_{z1}Ga_{1-z1}N (x2<z1≤1),
a part of the first compound semiconductor layer being provided between the third partial region and the first electrode portion.

### Technical Proposal 18

The semiconductor device according to Technical proposal 17, wherein
the third insulating portion is between the sixth partial region and another part of the first compound semiconductor layer in the second direction.

### Technical Proposal 19

The semiconductor device according to Technical proposal 17 or 18, wherein
a part of the first compound semiconductor layer is between a part of the first electrode portion and the sixth partial region in the first direction.

### Technical Proposal 20

The semiconductor device according to any one of technical proposals 1-19, wherein
the third partial region includes a first face facing the first electrode portion in the second direction,
the second semiconductor region includes a second face and a third face,
the third face faces the first semiconductor region,
the third face is between the first semiconductor region and the second face in the second direction, and
a first distance between the first face and the second face along the second direction is not less than 10 nm and not more than 500 nm.

According to the embodiment, a semiconductor device capable of improving characteristics is provided.

In the present specification, the term “electrically connected state” includes a state in which a plurality of conductors are physically in contact and a current flows between the plurality of conductors. The “state of being electrically connected” includes a state in which another conductor is inserted between the plurality of conductors and a current flows between the plurality of conductors.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the semiconductor devices such as electrodes, semiconductor layers, semiconductor regions, insulating layers, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first electrode;
a second electrode;
a third electrode including a first electrode portion, the third electrode being between the first electrode and the second electrode in a first direction from the first electrode to the second electrode;
a semiconductor layer:
a first insulating layer; and
a second insulating layer,
at least a part of the first insulating layer being provided between the third electrode and the semiconductor layer,
the semiconductor layer including:
a first semiconductor region including Alₓ₁Ga₁₋ₓ₁N (0≤x1<1); and
a second semiconductor region including Alₓ₂Ga₁₋ₓ₂N (x1<x2≤1),
the first semiconductor region including a first partial region, a second partial region, a third partial region, a fourth partial region, a fifth partial region, and a sixth partial region,
a second direction from the first partial region to the first electrode crossing the first direction,
a direction from the second partial region to the second electrode being along the second direction,
a direction from the third partial region to the first electrode portion being along the second direction,
a fourth position of the fourth partial region in the first direction being between a first position of the first partial region in the first direction and a third position of the third partial region in the first direction,
a fifth position of the fifth partial region in the first direction being between the third position and a second position of the second partial region in the first direction,
a sixth position of the sixth partial region in the first direction being between the third position and the fifth position,
the second semiconductor region including a first semiconductor portion and a second semiconductor portion,
at least a part of the first electrode portion being between the first semiconductor portion and the second semiconductor portion in the first direction,
the second insulating layer including a first insulating portion, a second insulating portion, and a third insulating portion,
the first semiconductor portion being between the fourth partial region and the first insulating portion in the second direction,
the second semiconductor portion being between the fifth partial region and the second insulating layer in the second direction,
the third insulating portion being in contact with the sixth partial region.

2. The semiconductor device according to claim 1, wherein
the third insulating portion is between the first electrode portion and the second semiconductor portion in the first direction.

3. The semiconductor device according to claim 1, wherein
at least a part of the second insulating layer is amorphous.

4. The semiconductor device according to claim 1, wherein
the second insulating layer includes silicon and at least one selected from the group consisting of nitrogen and oxygen.

5. The semiconductor device according to claim 1, wherein the second insulating layer includes silicon and nitrogen.

6. The semiconductor device according to claim 1, wherein
a part of the first electrode portion is between the fourth partial region and the sixth partial region in the first direction.

7. The semiconductor device according to claim 1, wherein
a first length of the third insulating portion along the first direction is not less than 200 nm and not more than 2000 nm.

8. The semiconductor device according to claim 1, wherein
the third insulating portion is between the sixth partial region and a part of the first electrode portion in the second direction.

9. The semiconductor device according to claim 1, wherein
the first insulating layer includes a first insulating region, a second insulating region, and a third insulating region,
at least a part of the first insulating region is between the first semiconductor portion and the first electrode portion in the first direction,
at least a part of the second insulating region is between the first electrode portion and the second semiconductor portion in the first direction, and
the third insulating region is between the third partial region and the first electrode portion in the second direction, 10. The semiconductor device according to claim 9, wherein
the third insulating portion is between the sixth partial region and at least a part of the second insulating region in the second direction.

11. The semiconductor device according to claim 10, wherein
the second insulating layer further includes a fifth insulating portion, and
the fifth insulating portion is between the second insulating region and the second semiconductor portion in the first direction.

12. The semiconductor device according to claim 9, wherein
the first semiconductor region further includes a seventh partial region,
a seventh position of the seventh partial region in the first direction is between the fourth position and the third position,
the second insulating layer further includes a fourth insulating portion,
the fourth insulating portion is in contact with the seventh partial region.

13. The semiconductor device according to claim 12, wherein
the fourth insulating portion is between the first semiconductor portion and the first electrode portion in the first direction.

14. The semiconductor device according to claim 12, wherein
a second length of the fourth insulating portion along the first direction is not less than 200 nm and not more than 2000 nm.

15. The semiconductor device according to claim 12, wherein
the fourth insulating portion is between the seventh partial region and at least a part of the first insulating region in the second direction.

16. The semiconductor device according to claim 10, wherein
the second insulating layer further includes a sixth insulating portion, and
the sixth insulating portion is between the first semiconductor portion and the first insulating region in the first direction.

17. The semiconductor device according to claim 1, further comprising:
a first compound semiconductor layer including Al_{z1}Ga_{1-z1}N (x2<z1≤1),
a part of the first compound semiconductor layer being provided between the third partial region and the first electrode portion.

18. The semiconductor device according to claim 17, wherein
the third insulating portion is between the sixth partial region and another part of the first compound semiconductor layer in the second direction.

19. The semiconductor device according to claim 17, wherein
a part of the first compound semiconductor layer is between a part of the first electrode portion and the sixth partial region in the first direction.

20. The semiconductor device according to claim 1, wherein
the third partial region includes a first face facing the first electrode portion in the second direction,
the second semiconductor region includes a second face and a third face,
the third face faces the first semiconductor region,
the third face is between the first semiconductor region and the second face in the second direction, and
a first distance between the first face and the second face along the second direction is not less than 10 nm and not more than 500 nm.
